(19) United States
(12) Patent Application Publication
(10) Pub. No.: US 2009/0205561 A1
(43) Pub. Date: Aug. 20, 2009

(54) METHOD FOR PRODUCING SILICON CARBIDE (SiC) CRYSTAL AND SILICON CARBIDE (SiC) CRYSTAL OBTAINED BY THE SAME

(75) Inventors: Yusuke Mori, Osaka (JP); Takatomo Sasaki, Osaka (JP); Fumio Kawamura, Osaka (JP); Minoru Kawahara, Osaka (JP); Yasuo Kitaoka, Osaka (JP)

Correspondence Address: HAMRE, SCHUMANN, MUELLER & LARSON, P.C., P.O. BOX 2902, MINNEAPOLIS, MN, 55402-0902, US

(73) Assignee: Osaka University, Suita-shi, Osaka (JP)

(21) Appl. No.: 12/305,313

(22) PCT Filed: Jun. 26, 2007
(86) PCT No.: PCT/JP2007/062826

§ 371 Date: Dec. 17, 2008

(30) Foreign Application Priority Data
Jun. 27, 2006 (JP) 2006-177382

(51) Int. Cl. C30B 9/10

(52) U.S. Cl. 117/79

(57) ABSTRACT

A production method is provided that enables to produce a large-sized bulk silicon carbide (SiC) crystal of high quality at low cost. A large-sized bulk silicon carbide (SiC) crystal of high quality can be obtained at a lower temperature by reacting silicon (Si) and carbon (C) produced from a lithium carbide such as dilithium acetylide (Li₂C₂) with each other in an alkali metal melt and thereby producing or growing a silicon carbide (SiC) crystal. FIG. 17 shows a high-resolution TEM (HR-TEM) image of the resultant 2H—SiC crystal. A preferable lithium carbide is dilithium acetylide (Li₂C₂). A preferable alkali metal melt is a melt of lithium alone.

### TECHNICAL FIELD

The present invention relates to methods for producing silicon carbide (SiC) crystals and silicon carbide (SiC) crystals obtained by the same.

### BACKGROUND ART

A silicon carbide (SiC) single crystal is a promising semiconductor material having a wide bandgap, high thermal conductivity, a high breakdown electric field, and high saturated electron velocity. Since a SiC single crystal has such properties, a semiconductor device produced therefrom can be operated at high temperatures, high speeds, and high output levels. Therefore semiconductor devices produced from SiC single crystals have great potential as, for example, on-vehicle power devices and energy devices.

Known conventional methods for growing SiC single crystals include, for example, a sublimation method, an Acheson process, and liquid phase growth. The sublimation method is a method in which SiC is used as a raw material and is heated to be sublimated and thereby a single crystal is deposited in a low temperature region. The Acheson process is a process in which carbon and silica stone are reacted with each other at a high temperature. The liquid phase growth is a method in which silicon is dissolved in a carbon crucible, carbon and silicon are reacted with each other at a high temperature, and thereby a single crystal is deposited. However, conventional growth methods have various problems as described below. First, in the sublimation method, a resultant single crystal is known to have, for example, a number of micropipes and stacking faults that are present therein. Conceivably, this is because when sublimating, the raw material is vaporized as Si, SiC₂, and Si₂C, the partial pressures thereof are difficult to control so as to have a stoichiometric composition, and therefore the aforementioned faults are formed. Furthermore, the sublimation method and the Acheson process require high temperatures. Moreover, the liquid phase growth has difficulty in growing large crystals due to a small amount of carbon dissolved in the silicon solution.

Recently, a method has been reported in which, in order to solve the aforementioned problems in the conventional methods, in the liquid phase growth method a raw material containing Si, C, and transition metal is melted to form a melt, a seed crystal then is brought into contact with the melt, and thereby a SiC single crystal is produced (Patent Documents 1, 2, and 3). In this method, a raw material whose composition allows Si_{0.8}Ti_{0.2} to be obtained is placed in a graphite crucible, the crucible is heated to 1850° C. in an Ar atmosphere at atmospheric pressure and thereby the raw material is dissolved, it then is maintained at 1850° C. for five hours so that graphite is dissolved in the melt, thereafter a 6H—SiC seed crystal is immersed in the melt, and this then is cooled to 1650° C. at a rate of 0.5° C./min. It has been reported that a 732-μm thick SiC crystal was formed by this method. However, this method has a problem in that high temperatures are required for crystal growth. That is, since Si has a melting point of 1414° C., C a melting point of 3500° C., Ti a melting point of 1675° C., and SiC a melting point of 2545° C., a high temperature condition of at least 1700° C. is required. Particularly, when a transition metal such as Ti is used, its high melting point makes it difficult to grow crystals at low temperatures. Accordingly, it is difficult to obtain crystal forms of, for example, 2H and 3C that are produced at low temperatures. Moreover, as described above, the sublimation method and the Acheson process also require high temperature conditions. Generally, in order to produce a large-sized SiC single crystal substrate of high quality at low cost, the crystal growth temperature needs to satisfy a low temperature condition of 1500° C. or lower.

[Patent Document 1] JP 2000-264790 A

[Patent Document 2] JP 2002-356397 A

[Patent Document 3] JP 2004-2173 A

### DISCLOSURE OF INVENTION

Therefore, the present invention is intended to provide a method for producing a silicon carbide (SiC) crystal that enables a large-sized bulk silicon carbide (SiC) crystal of high-quality to be produced at low cost.

In order to achieve the aforementioned object, a method for producing a silicon carbide (SiC) crystal of the present invention is characterized in that a silicon carbide (SiC) crystal, particularly a single crystal, is produced or grown by reacting carbon (C) produced from lithium carbide and silicon (Si) with each other in an alkali metal melt.

As described above, in the production method of the present invention, since lithium carbide such as dilithium acetylide (Li₂C₂) is used as a carbon (C) source and carbon (C) produced therefrom and silicon (Si) are reacted with each other in an alkali metal melt, a silicon carbide (SiC) crystal can be produced even under a temperature condition of, for example, 700° C. to 1414° C. Accordingly, the production method of the present invention enables a large-sized bulk silicon carbide (SiC) crystal of high-quality to be produced at low cost.

### BRIEF DESCRIPTION OF DRAWINGS

FIG. 1 is a schematic diagram showing an example of a production apparatus that is used for the production method of the present invention.

FIG. 2 is a photograph of Li₂C₂ obtained in Example 1 of the present invention.

FIG. 3 is a chart indicating the result of X-ray diffraction evaluation of a Li₂C₂ single crystal of Example 1 described above.

FIG. 4 is a photograph of Li₂C₂ obtained in Example 2 of the present invention.

FIG. 5 is a chart indicating the result of X-ray diffraction evaluation of a Li₂C₂ single crystal of Example 2 described above.

FIG. 6 is a photograph of another Li₂C₂ obtained in Example 2 of the present invention.

FIG. 7 is a chart indicating the result of X-ray diffraction evaluation of the aforementioned another Li₂C₂ single crystal of Example 2.

FIG. 8 is a chart indicating the result of X-ray diffraction evaluation of a residue of the aforementioned another Li₂C₂ single crystal of Example 2.

FIG. 9(A) is a photograph of a SiC single crystal obtained in Example 3 of the present invention.

FIG. 9(B) is another photograph of the SiC single crystal obtained in Example 3 described above.

FIG. 10 is a chart indicating the result of X-ray diffraction evaluation of a SiC single crystal of Example 3 described above.

FIG. 11(A) is a photograph of SiC single crystals obtained in Example 4 of the present invention.

FIG. 11(B) is another photograph of a SiC single crystal obtained in Example 4 described above.

FIG. 12 is a chart indicating the result of X-ray diffraction evaluation of a SiC single crystal of Example 4 described above.

FIG. 13 is a graph indicating the conditions for a temperature treatment in Example 5 of the present invention.

FIG. 14(A) is a photograph showing a SiC single crystal obtained in Example 5 described above.

FIG. 14(B) is a photograph showing step growth of the SiC single crystal obtained in Example 5 described above.

FIG. 15 is a chart indicating the result of X-ray diffraction evaluation of the SiC single crystal of Example 5 described above.

FIG. 16 is a photograph of a SiC single crystal obtained in Example 6 of the present invention.

FIG. 17 is a high-resolution transmission electron micrograph of the SiC single crystal of Example 6 described above.

FIG. 18 is a photograph showing a selected-area electron diffraction pattern of the SiC single crystal of Example 6 described above.

FIG. 19 is a chart indicating the result of X-ray diffraction evaluation of a SiC single crystal obtained in Example 8 of the present invention.

### BEST MODE FOR CARRYING OUT THE INVENTION

In the production method of the present invention, the aforementioned lithium carbide is not particularly limited, and examples thereof include Li₂C₂, LiC₁₆, LiC₄₀, LiC₁₂, LiC₂₄, LiC, LiC₆, Li₃C₈, and Li₂CH. One of them may be used individually or two or more of them may be used in combination. Among these, dilithium acetylide (Li₂C₂) is preferable.

In the production method of the present invention, it is preferable that the reaction be carried out in a heated atmosphere and the heating temperature be in a range of 700° C. to 1414° C. Furthermore, in the production method of the present invention, it is preferable that the reaction be carried out at a constant temperature for a fixed period of time.

In the production method of the present invention, it is preferable that the reaction be carried out in a tungsten (W) container or a platinum (Pt) container.

As described later, the lithium carbide may be prepared separately and then may be dissolved in the alkali metal melt, or a lithium melt may be used as the alkali metal melt and the lithium and carbon may be reacted with each other to produce lithium carbide in the lithium melt.

In the production method of the present invention, it is preferable that the alkali metal melt be a mixed melt containing silicon, the lithium carbide be dissolved in the mixed melt, and carbon (C) produced from the lithium carbide and the silicon (Si) be reacted with each other. In this case, it is preferable that the lithium carbide be produced and prepared by reacting Li and C with each other in an inert gas atmosphere under heating. Preferably, the heating temperature is in the range of 600° C. to 1000° C. Preferably, the inert gas atmosphere has a pressure lower than 1 atm (0.1 MPa).

In the production method of the present invention, the alkali metal melt may be a lithium (Li) melt, carbon may be added to the lithium melt to produce lithium carbide, and carbon (C) produced therefrom and silicon (Si) may be reacted with each other. In this case, the lithium melt may contain other components and may be, for example, a mixed melt with an alkali metal other than Li.

In the production method of the present invention, it is preferable that the alkali metal melt be a mixed melt containing lithium (Li) and silicon (Si). The growth temperature can be varied by changing the molar ratio between the lithium (Li) and the silicon (Si) in the mixed melt, and silicon carbide (SiC) can be grown, with a polymorphism of the growing silicon carbide being separated. In the production method of the present invention, the crystal form to be produced is not particularly limited and examples thereof include 6H—SiC, 4H—SiC, 2H—SiC, and 3C—SiC. Among these, 2H—SiC is preferable.

In the production method of the present invention, it is preferable that a silicon carbide (SiC) crystal prepared beforehand be used as a seed crystal and a new silicon carbide (SiC) crystal be grown, with the seed crystal serving as the nucleus.

The crystal of silicon carbide (SiC) to be produced by the production method of the present invention is preferably a single crystal. Similarly, the silicon carbide (SiC) crystal of the present invention is preferably a single crystal. The silicon carbide (SiC) crystal of the present invention is a silicon carbide (SiC) crystal obtained by the production method of the present invention described above. This silicon carbide (SiC) crystal is of higher quality as compared to that produced by a conventional method. Furthermore, the crystal form of the silicon carbide (SiC) crystal of the present invention is not particularly limited, and examples thereof include 6H—SiC, 4H—SiC, 2H—SiC, and 3C—SiC. Among these, 2H—SiC is preferable. The silicon carbide (SiC) crystal of the present invention can be increased in size as compared to conventional crystals and also can be a bulk-sized crystal.

A method for producing lithium carbide of the present invention is a method for producing a lithium carbide that is used for the method for producing a silicon carbide (SiC) crystal according to the present invention described above, wherein Li and C are reacted with each other in an inert gas atmosphere under heating. In this case, the heating temperature is preferably in the range of 600° C. to 1000° C., and the inert gas atmosphere has preferably a pressure lower than 1 atm (0.1 MPa). Lithium carbide of the present invention is that used for the method for producing a silicon carbide (SiC) crystal of the present invention described above.

A compound semiconductor of the present invention is a compound semiconductor including a silicon carbide (SiC) crystal, wherein the silicon carbide (SiC) crystal is a silicon carbide (SiC) crystal according to the present invention. Furthermore, a semiconductor device of the present invention is a semiconductor device including a compound semiconductor, wherein the compound semiconductor is a compound semiconductor of the present invention.

Hereinafter, the present invention is described in detail using examples.

In the production method of the present invention, the alkali metal flux is preferably a flux containing lithium (Li), and particularly preferably a flux of lithium alone. However, the present invention is not limited thereto. The aforementioned flux may contain other alkali metals such as sodium, potassium, rubidium, cesium, and francium, and may contain other elements such as alkaline earth metals (for example, beryllium, magnesium, calcium, strontium, barium, and radium).

In the production method of the present invention, it is preferable that the crystal be produced or grown in a heated atmosphere and the heating temperature be 1500° C. or lower. In the production method of the present invention, a specific condition for the heated atmosphere is, for example, in the range of 200° C. to 1500° C., preferably in the range of 400° C. to 1500° C., and more preferably in the range of 600° C. to 1400° C. Furthermore, as described later, in the production method of the present invention, it is preferable that the crystal be produced and grown in a pressurized atmosphere, and the condition therefor is, for example, in the range of 0.1 MPa to 100 MPa, preferably in the range of 0.1 MPa to 10 MPa, and more preferably in the range of 0.1 MPa to 1 MPa. Moreover, the crystal is produced or grown preferably in an inert gas atmosphere and more preferably in an argon (Ar) gas atmosphere.

In the production method of the present invention, the ratio among the alkali metal, which is a flux component, silicon (Si), and carbon (C) is not particularly limited. For instance, when lithium (Li) alone is used as the flux component, the ratio (molar ratio) among Li, Si, and C is, for example, Li:Si:C=1:0.01 to 100:0.01 to 100, preferably Li:Si:C=1:0.01 to 10:0.01 to 10, and more preferably Li:Si:C=1:0.01 to 1:0.01 to 1.

In the production method of the present invention, as described above, it is preferable that a silicon carbide (SiC) crystal prepared beforehand be used as a seed crystal and a new silicon carbide (SiC) crystal be grown, with the seed crystal serving as the nucleus. The seed crystal is preferably in the form of a substrate. In this case, it may include a silicon carbide (SiC) crystal formed in the form of a thin film on the surface of a substrate made of another material.

Next, an example of the production method of the present invention is described.

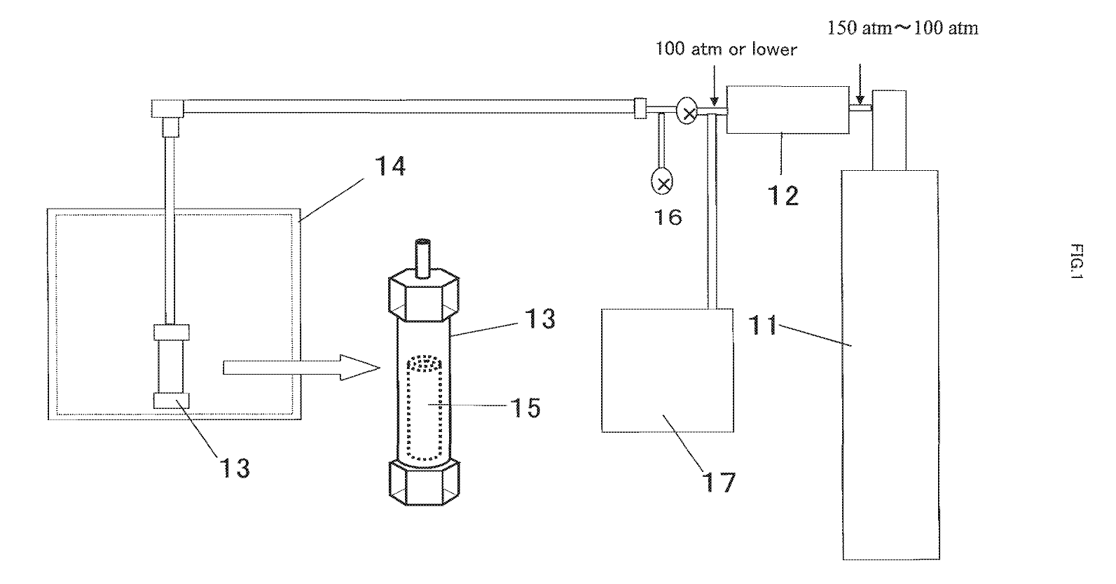

FIG. 1 shows an example of an apparatus that is used for the production method of the present invention. As shown in FIG. 1, this apparatus includes a gas tank 11, a pressure regulator 12, an electric furnace 14, a heat- and pressure-resistant container 13, and a vacuum pump 17. Examples of the electric furnace 14 include a resistive heater. A heat insulating material may be used for the electric furnace 14. In the resistive heater, when it is used at 1000° C. or lower, a kanthal wire can be used as a heating element, which allows the apparatus to have a simple configuration. Furthermore, in the resistive heater, when it is heated to 1500° C., for example, MoSi₂ is used. The gas tank 11 is filled with an inert gas such as argon (Ar). The gas tank 11 and vacuum pump 17 are connected to the pressure- and heat-resistant container 13 through pipes, and a pressure regulator 12 is disposed between them. In the gas tank 11, the gas pressure can be adjusted in the range of, for example, 1 atm to 100 atm (about 0.1 MPa to 10 MPa) by the pressure regulator 12 and then the gas can be supplied into the pressure- and heat-resistant container 13. Furthermore, the gas pressure also can be reduced by the vacuum pump 17. When the atmosphere pressure is under a pressurized condition, vaporization of lithium, a flux component, can be prevented. In FIG. 1, numeral 16 indicates a leak valve. The pressure- and heat-resistant container 13 to be used is, for example, a stainless steel container. The heat- and pressure-resistant container 13 is disposed inside the electric furnace 14 and is heated therewith. A crucible 15 is disposed inside the heat- and pressure-resistant container 13, and examples of the crucible material to be used include materials that are resistant to lithium metal, such as stainless steel (Steel Use Stainless; SUS) and a tungsten (W) or platinum (Pt) container. Furthermore, a crucible formed of a carbon material, such as a graphite crucible or a silicon carbide crucible, may be used. Raw materials, specifically lithium carbide such as dilithium acetylide (Li₂C₂), metal lithium (Li), and silicon (Si), are placed inside the crucible 15. In the present invention, other components also can be placed, and for example, doping impurities may be added. Examples of a P-type doping material include Al and B, and examples of an N-type doping material include N and P.

Production of a SiC crystal using this apparatus can be carried out, for example, as follows. First, in a glove box, lithium carbide such as dilithium acetylide (Li₂C₂) and high purity metal lithium (Li) and silicon (Si) are weighed and then are placed in the crucible 15. This crucible 15 then is set inside the pressure- and heat-resistant container 13. Since silicon tends to be oxidized, it is desirably in bulk form rather than a powder. Thereafter, argon gas is supplied into the heat- and pressure-resistant container 13 from the gas tank 11. In this case, the pressure thereof is adjusted to a predetermined pressure by the pressure regulator 12. The inside of the heat- and pressure-resistant container 13 then is heated by the electric furnace 14, and thereby lithium is dissolved first to form a melt of Li and Si inside the crucible 13 since the lithium has a boiling point of 1327° C. Subsequently, lithium carbide, a raw material, is dissolved in the melt, and thereby Si and C react with each other to produce a crystal. The temperature of the melt can be maintained in the range of, for example, 700° C. to 1414° C. Furthermore, changing the temperature and the raw material ratio makes it possible to control polymorphism of the crystal.

The growth mechanism of SiC crystal in the case of using dilithium acetylide is assumed, for example, as follows. That is, since the solubility of SiC is lower than that of dilithium acetylide in the Li—Si mixed melt, the carbon concentration in the melt become supersaturated with respect to the solubility of SiC when dilithium acetylide is intended to be dissolved in the melt until it becomes saturated. Therefore dilithium acetylide is dissolved continuously to be transformed to SiC crystals. However, this mechanism is an assumption and neither specifies nor limits the present invention.

In the production example described above, an increase in atmosphere pressure makes it possible further to increase the melt temperature and thereby improve the solubility of lithium carbide such as dilithium acetylide (Li₂C₂). The atmosphere pressure is as described above. For example, hydrocarbon gas such as methane or propane other than Ar gas also can be used as the atmospheric gas. Keeping the temperature of the mixed melt constant for a fixed period of time allows a SiC crystal to be produced or grown. Furthermore, it also is possible to use a seed crystal to epitaxially grow a SiC crystal on the substrate thereof.

In the production method of the present invention, there is a possibility that a further increase in growth temperature allows silicon carbide such as 4H—SiC or 6H—SiC to grow at a lower temperature than conventional one. Furthermore, in the production method of the present invention, in order to grow a 2H—SiC crystal selectively, it is preferable that, for example, growth temperature be controlled. The growth temperature for growing a 2H—SiC crystal selectively is, for example, in the range of 700° C. to 1400° C., preferably in the range of 700° C. to 1000° C., and more preferably in the range of 800° C. to 1000° C. or 700° C. to 900° C. Furthermore, 2H—SiC can be grown selectively also by suitably selecting other conditions (for instance, the raw material composition, flux composition, and pressure employed for growing) in addition to or instead of the growth temperature. The conditions for selectively growing the 2H—SiC crystal described above are examples and neither specify nor limit the present invention.

### EXAMPLES

Next, examples of the present invention are described. However, the present invention is neither specified nor limited by the following examples.

### Example 1

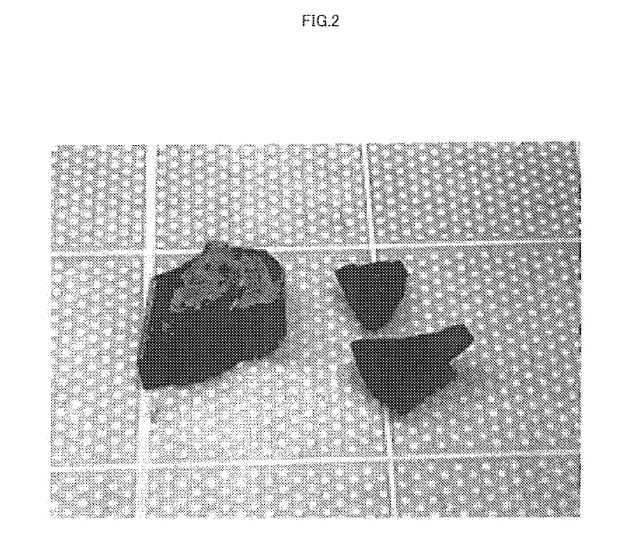

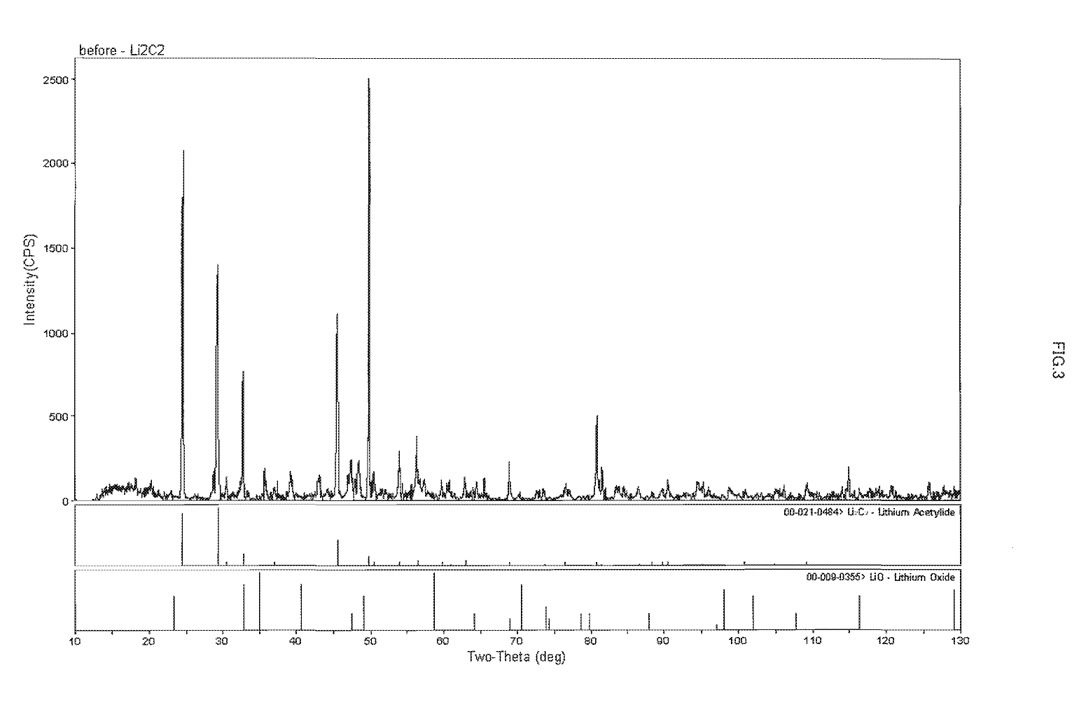

In this example, using the apparatus shown in FIG. 1, dilithium acetylide (Li₂C₂) was synthesized in an Ar atmosphere. That is, first, 0.85 g (=0.122 mol) of metal lithium (Li) and 1.20 g (=0.100 mol) of carbon (C) were placed inside a yttria (Y₂O₃) crucible 15 so as to have a molar ratio of Li:C=5:4. This crucible 15 was placed inside the pressure- and heat-resistant container (stainless steel container; the same applies below) 13. The inside of the pressure- and heat-resistant container 13 was substituted with an Ar atmosphere. Subsequently, the inside of the electric furnace 14 was heated to a temperature of 600° C., which then was maintained for 24 hours. Thereafter, it was cooled naturally to room temperature and thereby target dilithium acetylide was obtained. This dilithium acetylide is shown in the photograph in FIG. 2. This dilithium acetylide was evaluated using X-ray diffraction (XRD). FIG. 3 is a chart indicating the result of ω/2θ scan (the crystal and detector were rotated) of the X-ray diffraction described above. As shown in FIG. 3, a diffraction peak that agreed with peak data of dilithium acetylide (Li₂C₂) was obtained by this evaluation. The X-ray source is not particularly limited and can be, for example, CuKα radiation (the same applies below). Moreover, the aforementioned first crystal to be used for the X-ray diffraction also is not particularly limited, and can be, for example, an InP crystal or a Ge crystal (the same applies below).

### Example 2

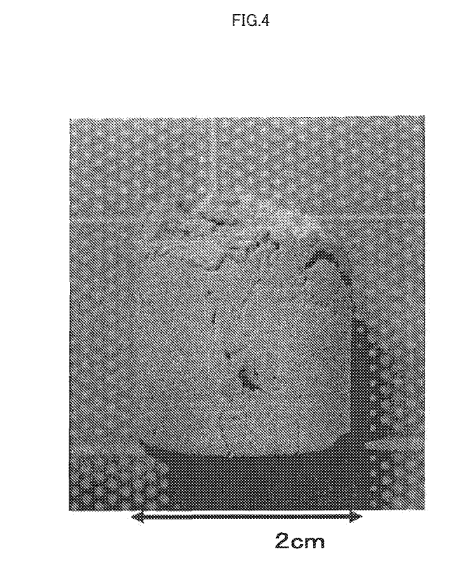

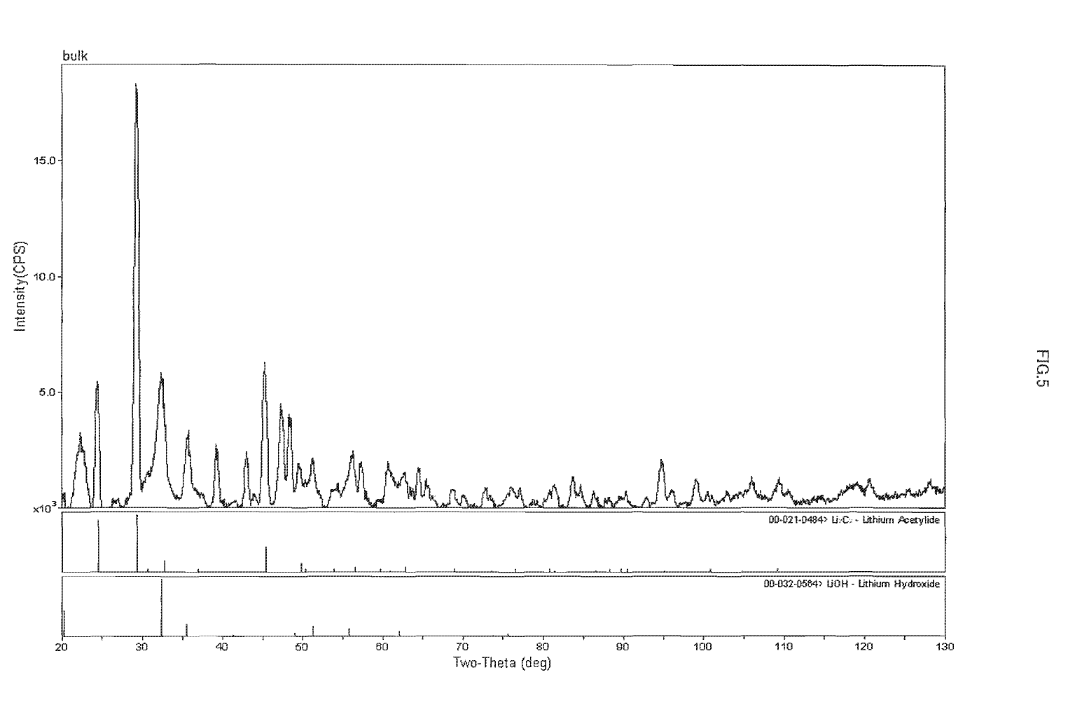

In this example, using the apparatus shown in FIG. 1, dilithium acetylide (Li₂C₂) was produced under a reduced pressure condition. That is, first, 0.65 g (=0.0929 mol) of metal lithium (Li) and 0.75 g (=0.0625 mol) of carbon (C) were placed inside a yttria (Y₂O₃) crucible 15 so as to have a molar ratio of Li:C=6:4. This crucible 15 was placed inside the pressure- and heat-resistant container 13. After the inside of the pressure- and heat-resistant container 13 was substituted with an Ar atmosphere, the pressure inside the pressure- and heat-resistant container 13 was reduced to the order of 10¹ Pa through the leak valve 16 using a rotary pump. Subsequently, the inside of the electric furnace 14 was heated to a temperature of 600° C., which then was maintained for 24 hours. Thereafter, it was cooled naturally to room temperature and thereby target dilithium acetylide was obtained. A photograph of this dilithium acetylide is shown in FIG. 4. This dilithium acetylide was evaluated using X-ray diffraction. FIG. 5 is a chart indicating the result of ω/2θ scan (the crystal and detector were rotated) of the X-ray diffraction described above. As shown in FIG. 5, a diffraction peak that agreed with peak data of dilithium acetylide (Li₂C₂) was obtained by this evaluation.

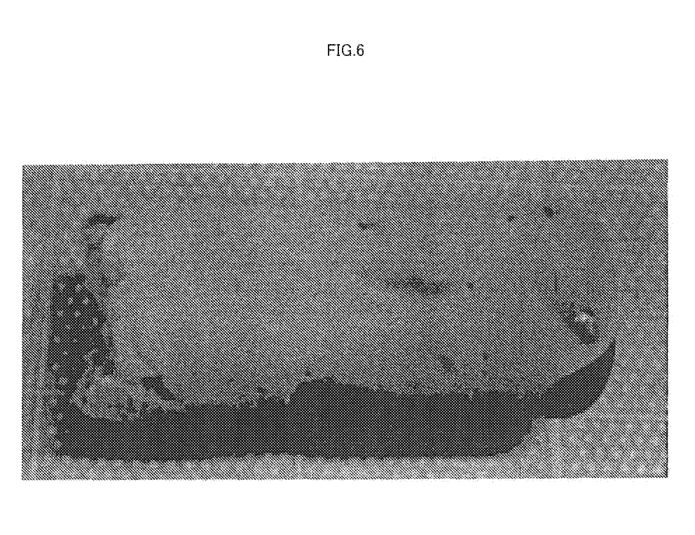

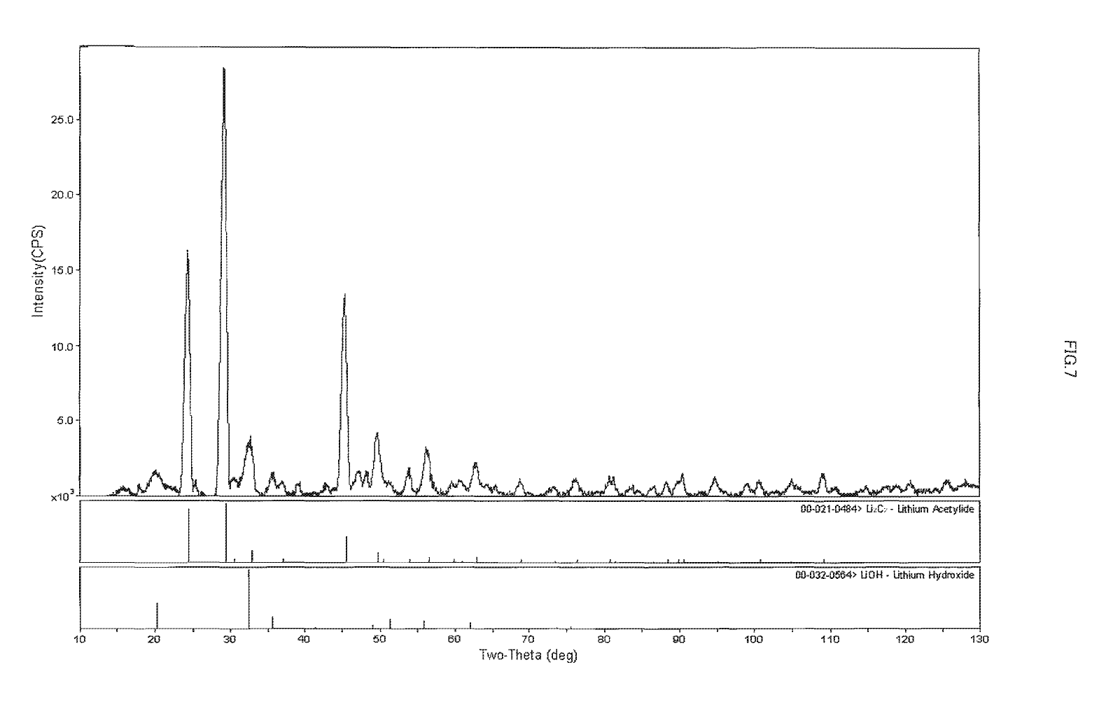

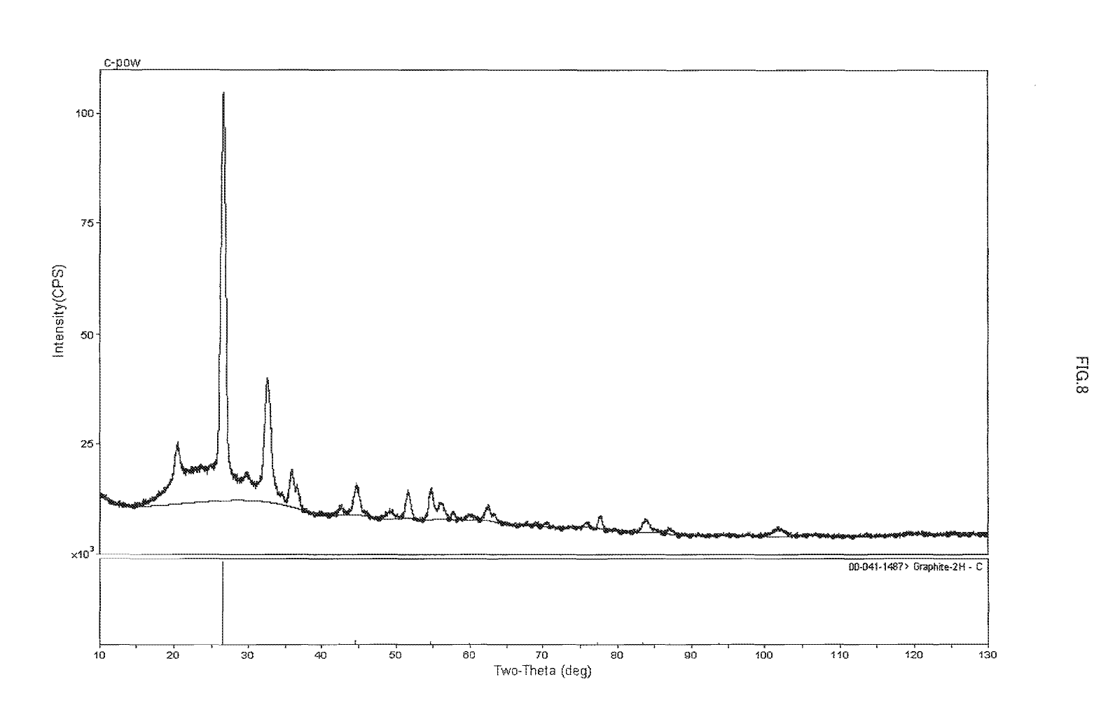

Further, 1.10 g (=0.16 mol) of metal lithium (Li) and 1.90 g (=0.16 mol) of carbon (C) were placed inside a yttria crucible so as to have a molar ratio of Li:C=5:5, and dilithium acetylide was produced in the same manner as described above. FIG. 6 shows a photograph of the dilithium acetylide thus obtained. This dilithium acetylide was evaluated using X-ray diffraction. FIG. 7 is a chart indicating the result of ω/2θ scan. As shown in FIG. 7, the peak of dilithium acetylide (Li₂C₂) and faint signals of lithium hydroxide were obtained. Furthermore, as shown in the photograph in FIG. 6, black powder was observed in part of the dilithium acetylide. FIG. 8 shows the result of X-ray diffraction of the powder. As shown in FIG. 8, the black powder was found to be mainly carbon (C). Since a peak of 29.5°, the first peak of dilithium acetylide (Li₂C₂), also was detected, it was found that dilithium acetylide also was contained. It is assumed that the reason why carbon remained unreacted is because metal lithium (Li) was vaporized during growth. However, this assumption neither specifies nor limits the present invention. In this example, synthesis was carried out at 600° C., but a further increase in temperature improves reactivity and thereby allows synthesis to be carried out in a shorter time.

### Example 3

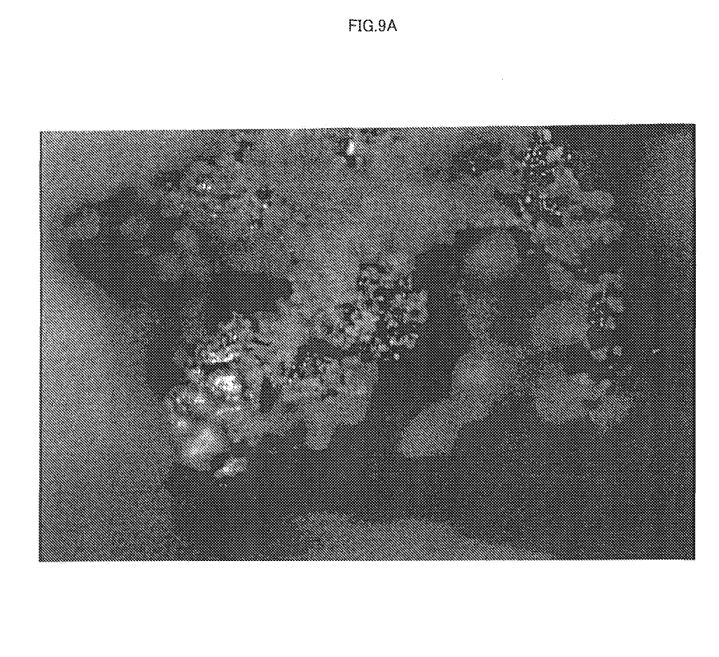

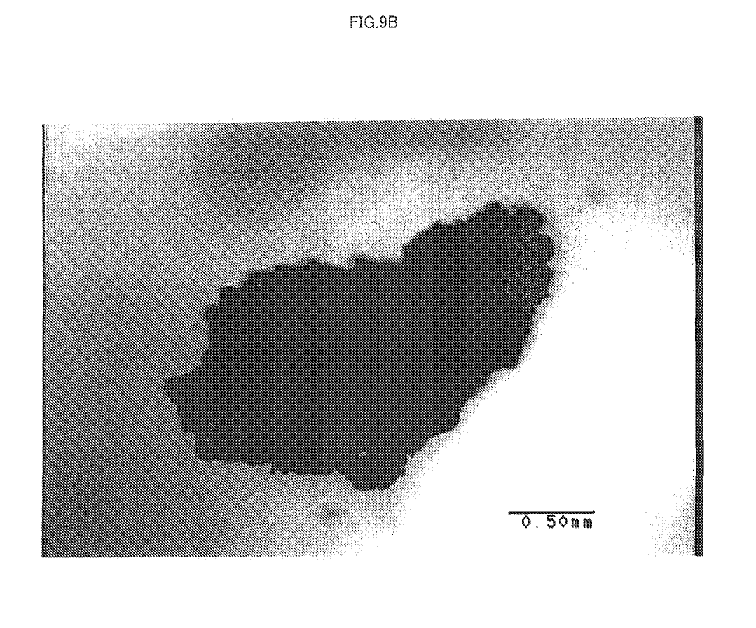

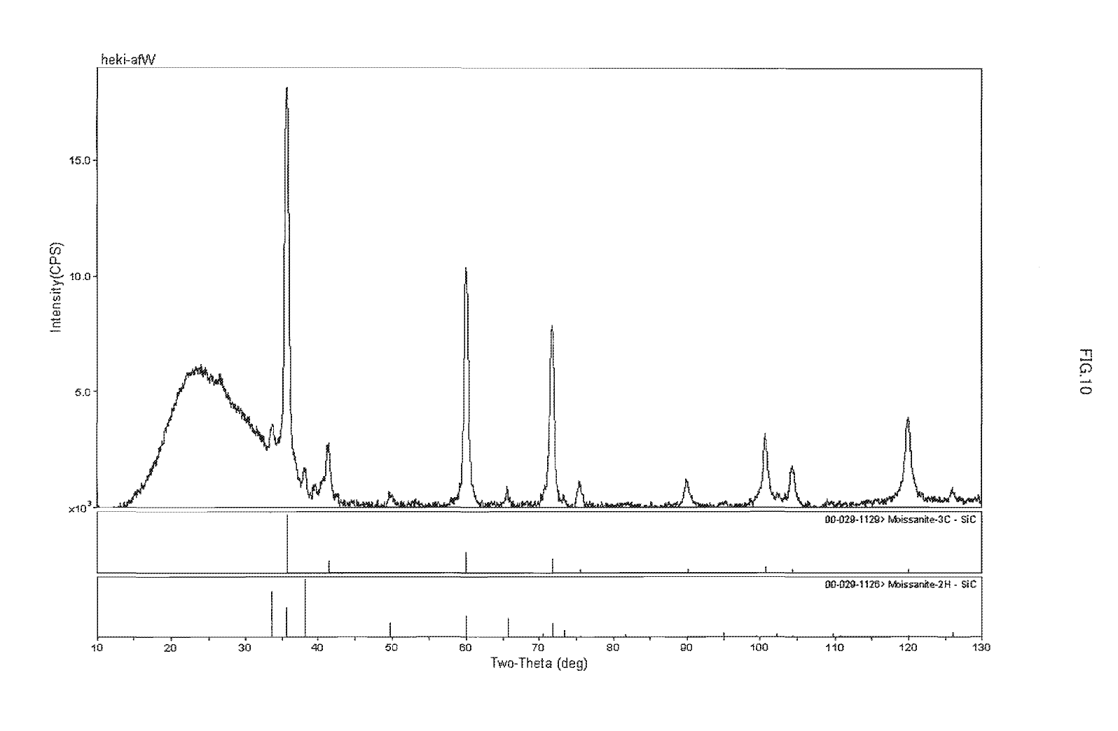

In this example, using the apparatus shown in FIG. 1, silicon carbide (SiC) single crystals were synthesized as follows, with the dilithium acetylide (Li₂C₂) synthesized in Examples 1 and 2 being used as raw materials. The crucible material used herein was tungsten (W) that was resistant to Li. Inside the crucible 15, 0.43 g (=0.062 mol) of metal lithium (Li), 0.74 g 0.026 mol) of silicon (Si), and 0.83 g (=0.022 mol) of dilithium acetylide (Li₂C₂) were placed so as to have a molar ratio of Li:Si=7:3. This crucible 15 was placed inside the pressure- and heat-resistant container 13. The inside of the pressure- and heat-resistant container 13 was substituted with an Ar atmosphere. Subsequently, the inside of the electric furnace 14 was heated to a temperature of 850° C. and then was maintained at a growth temperature of 850° C. for 48 hours. Thereafter, it was cooled naturally to room temperature. The product inside the tungsten (W) crucible 15 was treated with ethanol and water and thereby residual lithium (Li) and dilithium acetylide (Li₂C₂) were removed. The resultant SiC single crystal is shown in the photographs in FIGS. 9(A) and 9(B). Furthermore, X-ray diffraction evaluation of the resultant SiC single crystal was carried out. FIG. 10 is a chart indicating the result of ω/2θ scan (the crystal and detector were rotated) of the X-ray diffraction described above. As shown in FIG. 10, a strong peak of 3C—SiC was obtained. Moreover, a diffraction peak that agreed with the peak data of 2H—SiC, hexagonal crystal, was found, although it was faint.

### Example 4

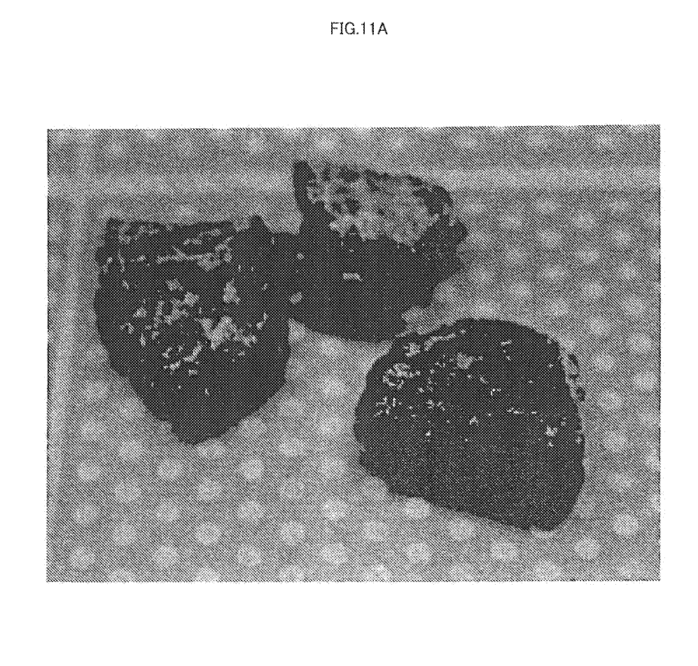

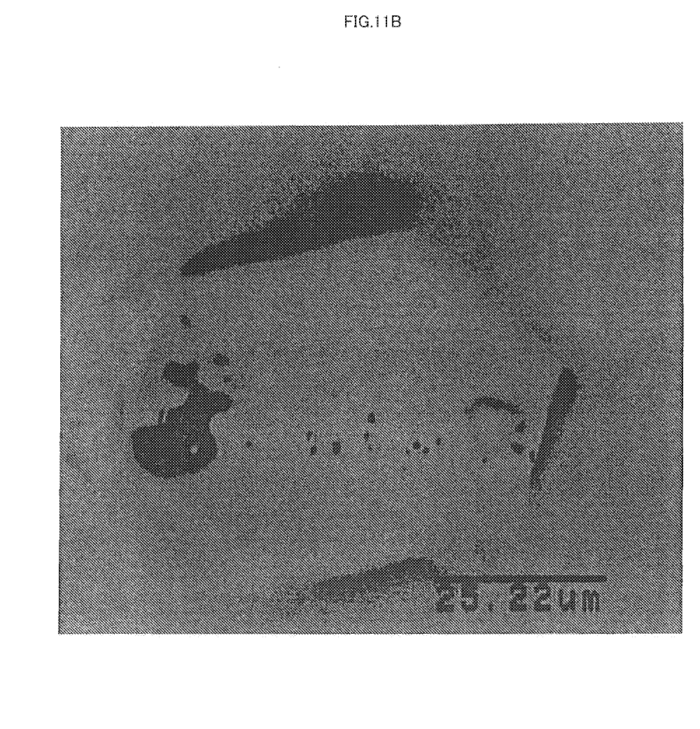

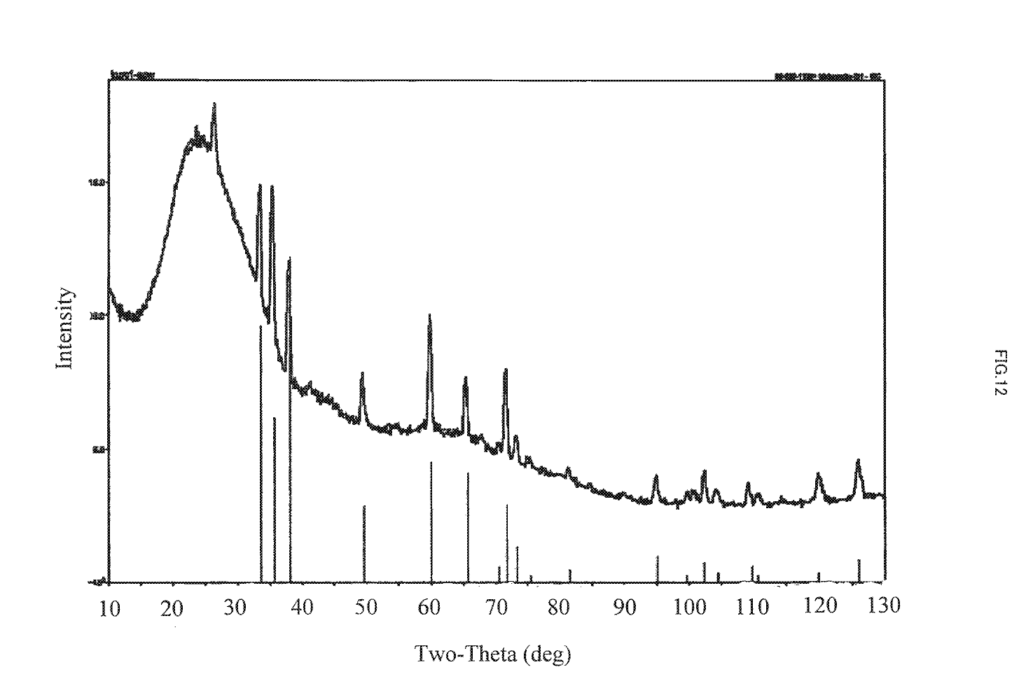

In this example, using the apparatus shown in FIG. 1, silicon carbide (SiC) single crystals were synthesized as follows, with dilithium acetylide (Li₂C₂) synthesized in Examples 1 and 2 being used as raw materials. The crucible material used herein was tungsten (W) that was resistant to Li. Inside the crucible 15, 0.43 g (=0.062 mol) of metal lithium (Li), 1.74 g 0.062 mol) of silicon (Si), and 1.17 g (=0.031 mol) of dilithium acetylide (Li₂C₂) were placed so as to have a molar ratio of Li:Si=5:5. This crucible 15 was placed inside the pressure- and heat-resistant container 13. The inside of the pressure- and heat-resistant container 13 was substituted with an Ar atmosphere. Subsequently, the inside of the electric furnace 14 was heated to a temperature of 800° C. and then was maintained at a growth temperature of 800° C. for 48 hours. Thereafter, it was cooled naturally to room temperature. The product inside the tungsten (W) crucible 15 was treated with ethanol and water and thereby residual lithium (Li) and dilithium acetylide (Li₂C₂) were removed. The resultant SiC single crystals are shown in the photographs in FIGS. 11(A) and 11(B). Furthermore, X-ray diffraction evaluation of the resultant SiC single crystals was carried out. FIG. 12 is a chart indicating the result of ω/2θ scan (the crystal and detector were rotated) of the X-ray diffraction described above. As shown in FIG. 12, a strong peak of 2H—SiC was obtained.

It can be understood from Examples 1 to 4 described above that dilithium acetylide (Li₂C₂) is dissolved in a solution containing lithium (Li) and silicon (Si) to supply carbon (C), and this carbon (C) and silicon (Si) contained in the solution react with each other and thereby silicon carbide (SiC) is synthesized. When the reaction is carried out in a region having a constant temperature, it is possible to selectively grow a polytype of silicon carbide by changing the growth temperature and the composition ratio of raw materials.

### Example 5

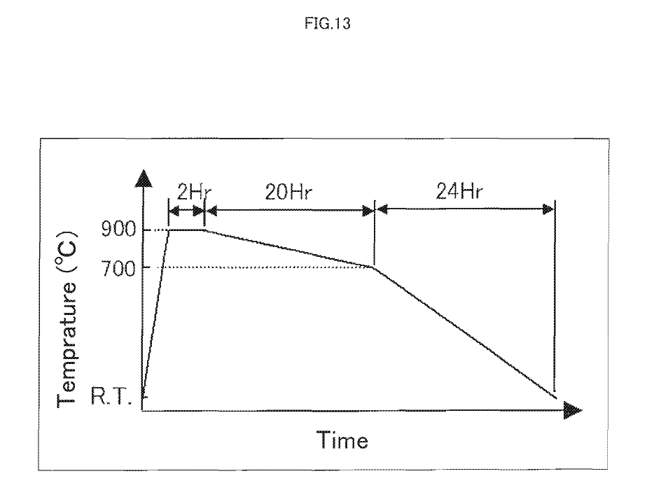

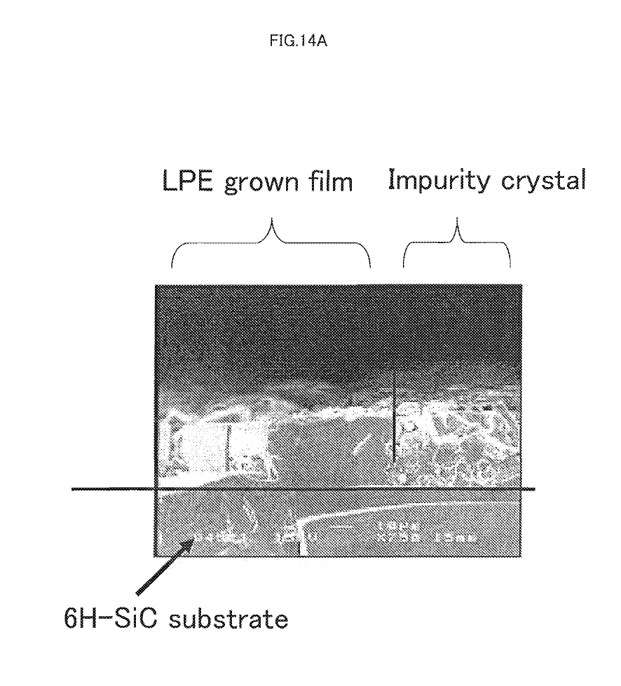

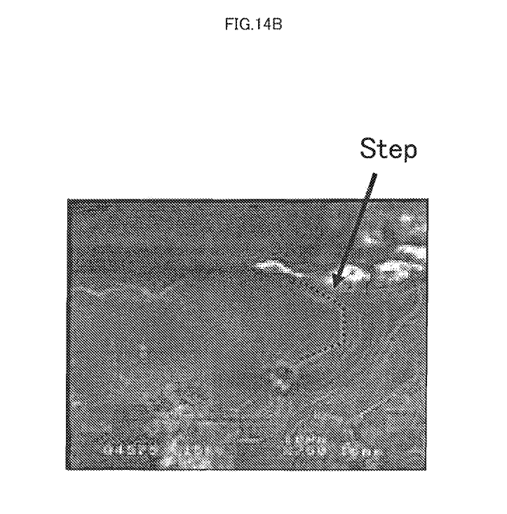

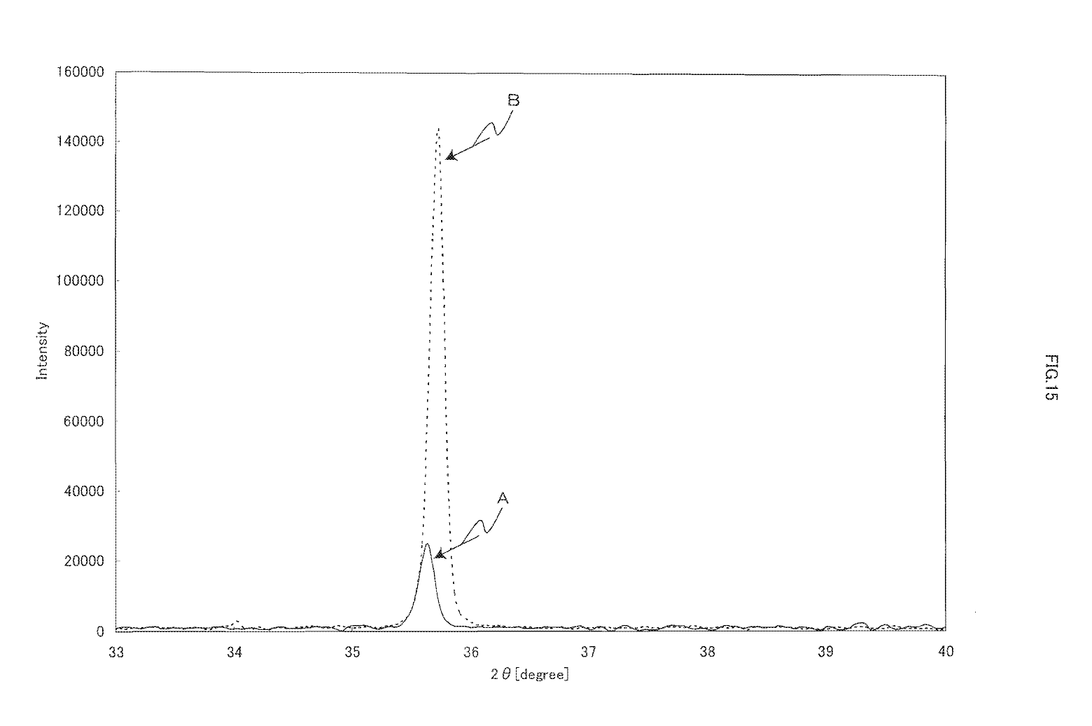

In this example, using the apparatus shown in FIG. 1, a silicon carbide (SiC) single crystal was synthesized by liquid phase epitaxial (LPE) growth, with graphite being used as a carbon source (C). The crucible material used herein was tungsten (W), which was resistant to Li. Inside the crucible 15, 1.14 g (=0.163 mol) of metal lithium (Li), 2.10 g (=0.075 mol) of silicon (Si), and 1.49 g (=0.124 mol) of graphite (C) were placed so as to have a molar ratio of Li:Si:C=6.5:3:5. Furthermore, a 6H—SiC substrate was used as a seed crystal, and the substrate was placed inside the crucible 15. This crucible 15 was placed inside the pressure- and heat-resistant container 13. The inside of the pressure- and heat-resistant container 13 was substituted with an Ar atmosphere. Subsequently, as shown in the chart in FIG. 13, the inside of the electric furnace 14 was heated from room temperature (R.T.) to 900° C. and then was maintained at 900° C. for two hours. Thereafter, the temperature was decreased to 700° C. over 20 hours at a constant rate and further to room temperature over 24 hours at a constant rate. The product inside the crucible 15 was treated with ethanol and water and thereby the residue was removed. Images of the resultant SiC single crystal that was observed with a scanning electron microscope (SEM) are shown in FIGS. 14(A) and 14(B). In both FIGS. 14(A) and 14(B), the magnification is 750-fold. As shown in FIG. 14(A), an LPE grown film of SiC with a thickness of approximately 30 μm was observed on the 6H—SiC substrate. In FIG. 14(A), the left side on the substrate is the LPE grown film (SiC single crystal) and the right side is a region where impurity crystals were stacked. Furthermore, as shown in FIG. 14(B), a step with an angle of 120° was observed in the SiC single crystal. Based on these points, the SiC single crystal formed on the substrate can be said to be a hexagonal crystal. Moreover, with respect to the SiC single crystal, X-ray diffraction was carried out. This result is shown in the chart in FIG. 15. This chart indicates the result of ω/2θ scan (the crystal and detector were rotated) of the X-ray diffraction. In FIG. 15, the solid line indicates the chart of the resultant SiC single crystal and the dotted line indicates the chart of the 6H—SiC substrate. As shown in FIG. 15, the peak (arrow A) of the resultant SiC single crystal was different from the peak (arrow B) of the 6H—SiC substrate and was substantially the same peak as the theoretical value of 2H—SiC (002).

### Example 6

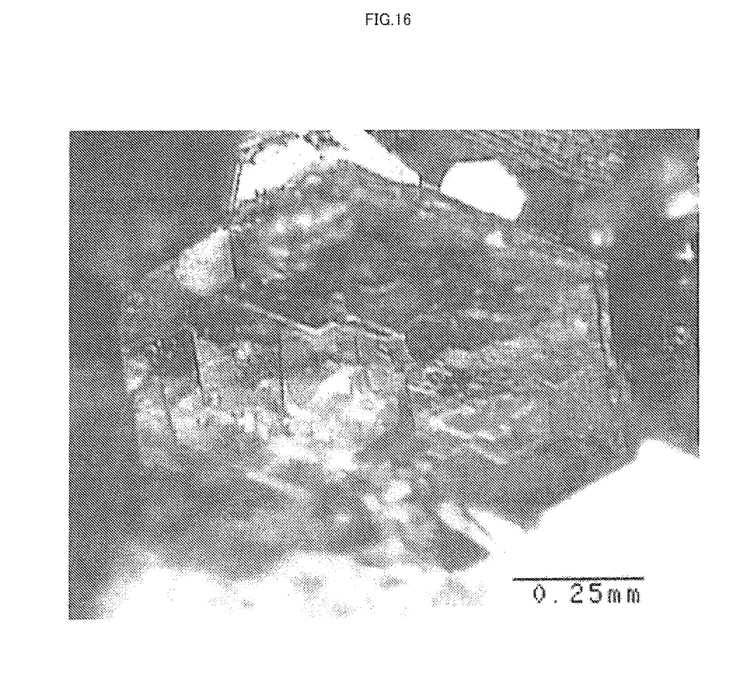

In this example, using the apparatus shown in FIG. 1, a silicon carbide (SiC) single crystal was synthesized as follows, with graphite being used as a carbon source (C). The crucible material used herein was tungsten (W) that was resistant to Li. Inside the crucible 15, 1.38 g (=0.197 mol) of metal lithium (Li), 2.40 g (=0.0857 mol) of silicon (Si), and 0.855 g (=0.0713 mol) of graphite (C) were placed so as to have a molar ratio of Li:Si:C=7:3:2.5. This crucible 15 was placed inside the pressure- and heat-resistant container 13. The inside of the pressure- and heat-resistant container 13 was substituted with an Ar atmosphere. Subsequently, the inside of the electric furnace 14 was heated from room temperature (R.T.) to 800° C. and then was maintained at a growth temperature of 800° C. for 48 hours. Thereafter, it was cooled to room temperature. The product inside the crucible 15 was treated with ethanol and water and thereby the residue was removed. The resultant SiC single crystal is shown in the optical micrograph in FIG. 16. As shown in FIG. 16, a SiC single crystal, hexagonal crystal, was obtained with the largest diameter thereof being 1 mm. This SiC single crystal was observed with a high-resolution transmission electron microscope (HR-TEM) and also was subjected to selected-area electron diffraction. A field-emission transmission electron microscope (HF-TEM), HF-2100, manufactured by Hitachi, Ltd. was used as the HR-TEM, and the SiC single crystal was observed at 150000-fold magnification. Furthermore, in the selected-area electron diffraction, the accelerating voltage was 200 kV, and the crystal surface to be subjected to diffraction was a (11-20) plane.

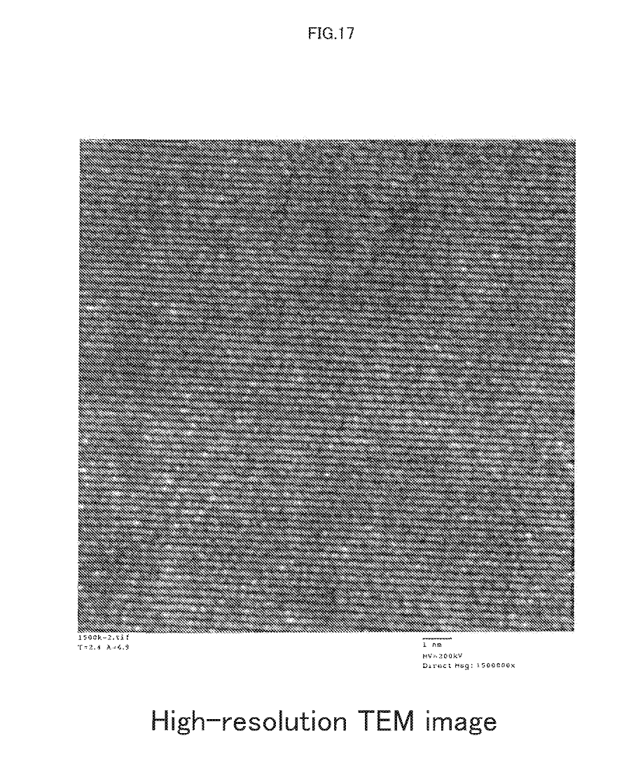

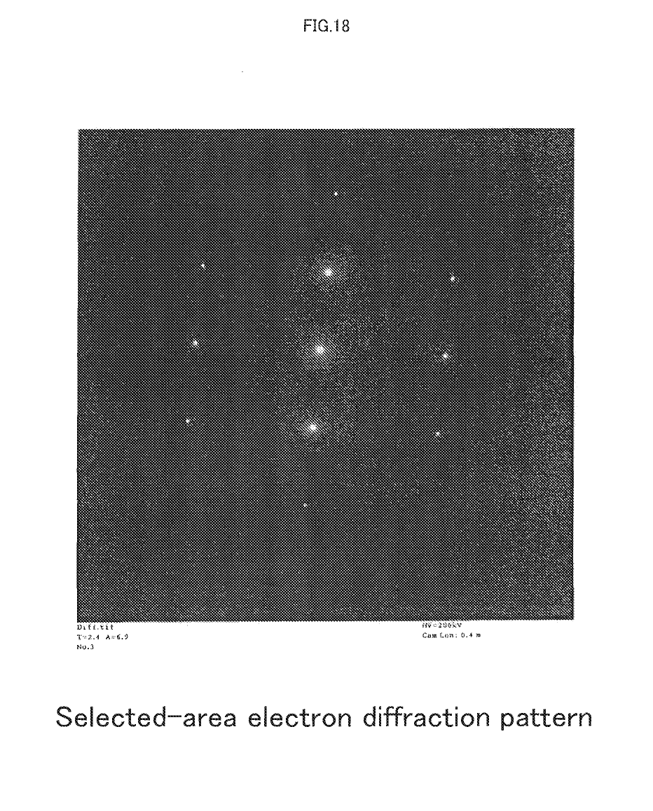

FIG. 17 shows the photograph of high-resolution TEM (HR-TEM) of the SiC single crystal according to this example. As shown in FIG. 17, as a result of observation with the HR-TEM, 2H structure was found in which every two layers of SiC molecules had the same stacking pattern. Furthermore, the result of selected-area electron diffraction pattern of the SiC single crystal according to this example is shown in the photograph in FIG. 18. As shown in FIG. 18, the selected-area electron diffraction pattern also coincided with the theoretically-expected diffraction pattern of 2H—SiC. From these results, the SiC single crystal obtained in this example can be said to be 2H—SiC.

### Example 7

In this example, using the apparatus shown in FIG. 1, a silicon carbide (SiC) single crystal was synthesized as follows, with graphite being used as a carbon source (C). The crucible material used herein was tungsten (W) that was resistant to Li. Inside the crucible 15, 0.717 g (=0.102 mol) of metal lithium (Li), 1.23 g (=0.0439 mol) of silicon (Si), and 0.878 g (=0.0732 mol) of graphite (C) were placed so as to have a molar ratio of Li:Si:C=7:3:5. This crucible 15 was placed inside the pressure- and heat-resistant container 13. The inside of the pressure- and heat-resistant container 13 was substituted with an Ar atmosphere. Subsequently, the inside of the electric furnace 14 was heated from room temperature (R.T.) to 800° C. and then was maintained at a growth temperature of 800° C. for a fixed period of time. Thereafter, it was cooled to room temperature. The product inside the crucible 15 was treated with ethanol and water and thereby the residue was removed. Four periods of time, specifically, 2 hours, 12 hours, 48 hours, and 120 hours, were employed as the fixed period of time (growth time) for which the temperature was maintained after being heated. The yields (%) of the SiC single crystals thus obtained were calculated. As indicated by the following formula, the yields (%) of the SiC single crystals were calculated by dividing the number (n_{SiC}) of moles of a resultant SiC single crystal by the number (n_{Si}) of moles of Si used as a raw material. The yields (%) of the SiC single crystals thus calculated with respect to the respective growth times are indicated below in Table 1.

Yield(%) of SiC single crystal=n_{SiC}/n_{Si}×100

TABLE 1

Growth Time

| | 2 hours | 12 hours | 48 hours | 120 hours |
|---|---|---|---|---|
| Yield (%) | 37.1 | 49.2 | 52.0 | 46.2 |

From the result indicated in Table 1 above, it can be said that growth is substantially completed in a growth time of two hours in this example.

### Example 8

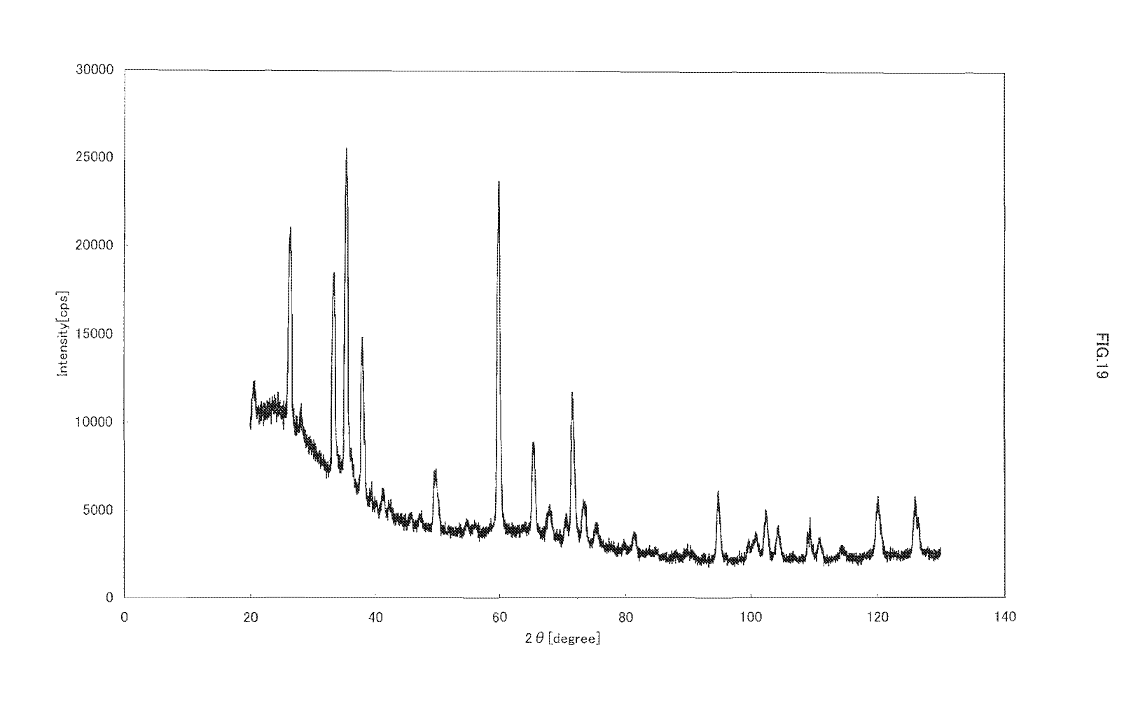

A SiC single crystal was produced in the same manner as in Example 6 except that the growth temperature was 900° C. With respect to the resultant SiC single crystal, X-ray diffraction was carried out. This result is shown in the chart in FIG. 19. This chart shows the result of ω/2θ scan (the crystal and detector were rotated) of the X-ray diffraction. As shown in FIG. 19, the peak of the resultant SiC single crystal was substantially the same peak as the theoretical value of 2H—SiC.

### INDUSTRIAL APPLICABILITY

As described above, the production method of the present invention enables to produce a large-sized bulk silicon carbide (SiC) crystal of high-quality at low cost. The silicon carbide (SiC) crystals obtained by the production method of the present invention can be used suitably as semiconductor devices used for on-vehicle power devices or energy devices, for example. The use of the silicon carbide (SiC) crystals is not limited and they have a wide range of application.

1. A method for producing a silicon carbide (SiC) crystal,
wherein a silicon carbide (SiC) crystal is produced or grown by reacting carbon (C) produced from lithium carbide and silicon (Si) with each other in an alkali metal melt.

2. The method according to claim 1, wherein the lithium carbide is at least one compound selected from the group consisting of Li₂C₂, LiC₁₆, LiC₄₀, LiC₁₂, LiC₂₄, LiC, LiC₆, Li₃C₈, and Li₂CH.

3. The method according to claim 1, wherein the lithium carbide is dilithium acetylide (Li₂C₂).

4. The method according to claim 1, wherein the reaction is carried out under heating and the heating temperature is in a range of 700° C. to 1414° C.

5. The method according to claim 1, wherein the reaction is carried out at a constant temperature for a fixed period of time.

6. The method according to claim 1, wherein the reaction is carried out in a tungsten (W) container or a platinum (Pt) container.

7. The method according to claim 1, wherein the lithium carbide is prepared, the alkali metal melt is a mixed melt containing silicon, the lithium carbide is dissolved in the mixed melt, and carbon (C) produced from the lithium carbide and the silicon (Si) are reacted with each other.

8. The method according to claim 7, wherein the lithium carbide is produced and prepared by reacting Li and C with each other in an inert gas atmosphere under a heated condition.

9. The method according to claim 8, wherein the heating temperature is in a range of 600° C. to 1000° C.

10. The method according to claim 8, wherein the inert gas atmosphere has a pressure lower than 1 atm (0.1 MPa).

11. The method according to claim 1, wherein the alkali metal melt is a lithium (Li) melt, carbon is added to the lithium melt to produce the lithium carbide, and carbon (C) produced from the lithium carbide and the silicon (Si) are reacted with each other.

12. The method according to claim 1, wherein the alkali metal melt is a mixed melt comprising lithium (Li) and silicon (Si), growth temperature can be varied by changing a molar ratio between the lithium (Li) and the silicon (Si) in the mixed melt, and silicon carbide (SiC) is grown, with a polymorphism of the growing silicon carbide being separated.

13. The method according to claim 1, wherein a silicon carbide (SiC) crystal prepared beforehand is used as a seed crystal and a new silicon carbide (SiC) crystal is grown, with the seed crystal serving as a nucleus.

14. The method according to claim 1, wherein the silicon carbide (SiC) crystal is 2H—SiC.

15-22. (canceled)
